(19) United States
(12) Patent Application Publication
(10) Pub. No.: US 2025/0364514 A1
(43) Pub. Date: Nov. 27, 2025

(54) DISPLAY DEVICE

(71) Applicant: AUO Corporation, Hsinchu City (TW)

(72) Inventor: Chen-Yu SHIEH, Hsinchu City (TW)

(21) Appl. No.: 18/951,725

(22) Filed: Nov. 19, 2024

(30) Foreign Application Priority Data
May 27, 2024 (TW) 113119592

(51) Int. Cl. H01L 25/16; H01L 23/00; H01L 23/04; H01L 23/31; H01L 23/538; H01L 33/06

(52) U.S. Cl. CPC H01L 25/167; H01L 23/04; H01L 23/3157; H01L 23/538; H01L 24/48; H10H 20/812; H01L 2224/48227

(57) ABSTRACT

A display device includes a wiring substrate, a control chip, a light emitting component, a plurality of bonding wires, a protective plastic substance, and a fence. The wiring substrate has a plurality of first pads. The control chip is disposed on the wiring substrate and includes a plurality of second pads. The light emitting component is disposed on the control chip and electrically connected to the control chip. Each of the second pads is located between at least one first pad and the light emitting component. The bonding wires are connected to the first pads and the second pads respectively. The protective plastic substance is disposed on the wiring substrate and encapsulates the bonding wires. The fence is disposed on the wiring substrate and surrounds the first pads and the protective plastic substance.

### CROSS-REFERENCE TO RELATED APPLICATION

This application claims priority to Taiwan Application Serial Number 113119592, filed May 27, 2024, which is herein incorporated by reference in its entirety.

### BACKGROUND

### Field of Invention

The present disclosure relates a display device, and in particular to a display device made by wire-bonding.

### Description of Related Art

Now some display devices, for example, the display devices of wearable electronic apparatuses usually are made by wire-bonding, so the abovementioned display device has a plurality of bonding wires. These bonding wires are covered by a protective plastic substance to protect these bonding wires from short circuit, where the abovementioned protective plastic substance should be cured, and then can cover and protect the bonding wires.

However, the protective plastic substance before curing is flowing. Accordingly, in the process of placing the protective plastic substance, the protective plastic substance overflows easily, resulting in the distribution area of the protective plastic substance is difficult to be controlled, thereby causing some problems. For example, it is hard to control the using amount of the protective plastic substance, thereby causing waste. And the components that are not expected or suitable to be covered by the protective plastic substances are covered by the protective plastic substance.

### SUMMARY

At least one embodiment of the present disclosure provides a display device which utilizes a fence to control the distribution region of the protective plastic substance to avoid the overflow of the protective plastic substance.

At least one embodiment of the present disclosure provides a display device including a wiring substrate, a control chip, a light emitting component, a plurality of bonding wires, a protective plastic substance, and a fence. The wiring substrate has an assembly surface and a plurality of first pads. The control chip is disposed on the assembly surface and has a first surface and a second surface. The second surface is located between the assembly surface and the first surface. The control chip comprises a plurality of second pads disposed on the first surface. The light emitting component is disposed on the first surface and is electrically connected to the control chip. Each of the second pads is located between at least one first pad and the light emitting component. These bonding wires are connected to the first pads and the second pads respectively. The protective plastic substance is disposed on the assembly surface and encapsulates the bonding wires. The fence is disposed on the assembly surface and surrounds the first pads and the protective plastic substance.

According to the above description, the abovementioned fence can limit the area in which the protective plastic substance can be distributed, i.e. control the distribution area of the protective plastic substance to prevent the overflow of the protective plastic substance.

### BRIEF DESCRIPTION OF THE DRAWINGS

FIG. 1 is a three-dimensional schematic diagram of a wearable electronic device employing a display device of at least one embodiment of the present disclosure.

FIG. 2 is a cross-section schematic diagram of an image projector along a line 2-2 of FIG. 1.

FIG. 3A is a three-dimensional schematic diagram of the display device of FIG. 2.

FIG. 3B is a three-dimensional schematic diagram of the display device in FIG. 3A after removing protective plastic substance.

FIG. 3C is a cross-section schematic diagram along a line 3C-3C of FIG. 3A.

FIG. 4A is a three-dimensional schematic diagram of a display device of at another embodiment of the present disclosure.

FIG. 4B is a three-dimensional schematic diagram of the display device in FIG. 4A without the protective plastic substance.

FIG. 4C is a cross-section schematic diagram along a line 4C-4C of FIG. 4A.

FIG. 5A to FIG. 5C are top view schematic diagrams of manufacturing a display device of at least one embodiment of the present disclosure.

FIG. 6 is a top view schematic diagram of a display device of at least one embodiment of the present disclosure.

FIG. 7 is a top view schematic diagram of a display device of another embodiment of the present disclosure.

### DETAILED DESCRIPTION

In the following text, in order to clearly present the technical features of this case, the dimensions (such as length, width, thickness and depth) of the components (such as layers, electrodes, base boards, regions, etc.) in the drawings are expressed in unequal proportions to be enlarged, and the number of some components will be reduced. Therefore, the description and explanation of the embodiments below are not limited to the number of components and the sizes and shapes of the components in the drawings, but should cover the size, shape, and deviations in both caused by actual manufacturing processes and/or tolerances. For example, regions shown or described as flat may typically have rough and/or non-linear characteristics. Additionally, the acute angles shown can be rounded. Therefore, the components shown in the drawings of this case are mainly for illustration, and are not intended to accurately depict the actual shapes of the components, nor are they intended to limit the patent scope of this case.

Secondly, words such as “about”, “approximate”, or “substantially” as they appear in this case cover not only clearly stated values and ranges of values, but also permissible range of deviation as understood by a person having ordinary skill in the art (PHOSITA) or in the field to which the disclosure belongs, where such ranges of deviation can be determined by the error in measurement, which may arise, for example, from limitations of either the measurement system or the process conditions. In addition, “about” may be expressed within one or more standard deviations of the above values, such as ±30%, ±20%, ±10%, or ±5%. Words such as “about”, “approximately”, or “substantially” in this text of this case can be used to select an acceptable range of deviation or standard deviation based on optical, etching, mechanical, or other properties, rather than applying a single standard deviation to all of the above properties, such as optical, etching, mechanical, and other properties.

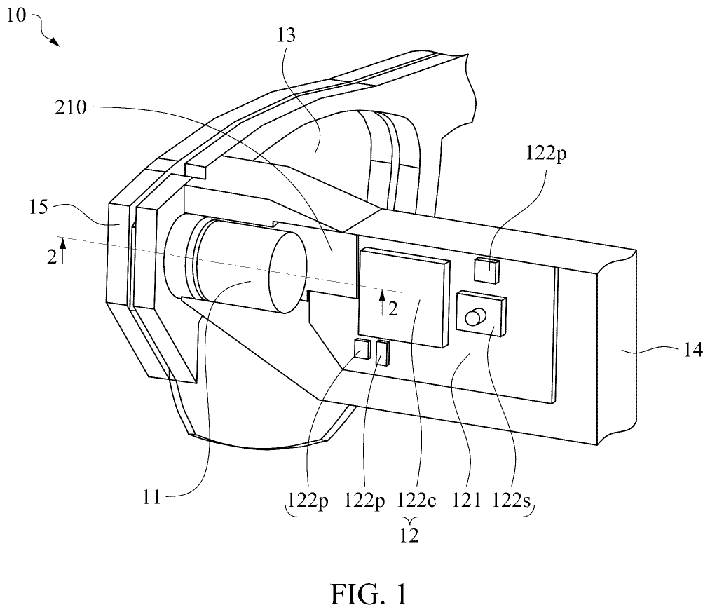

FIG. 1 is a three-dimensional schematic diagram of a wearable electronic device employing a display device of at least one embodiment of the present disclosure. Referring to FIG. 1, a wearable electronic device 10 includes an image projector 11 and a printed circuit board assembly (PCBA) 12, in which the PCBA 12 is electrically connected to the image projector 11. The PCBA 12 includes a circuit board 121 and a plurality of electric components 122c, 122p and 122s, where the electric components 122p can be a passive component and the electronic components 122s can be a switch. The electronic components 122c can be a processor or controller, such as a microcontroller unit (MCU), and the electronic components 122c can control the image projector 11 to project an image via the circuit board 121.

In the embodiment shown in FIG. 1, the wearable electronic device 10 can be a pair of smart glasses with Augmented Reality (AR), and includes eyeglasses 13, a temple 14, and a glasses frame 15, where the image projector 11 and the PCBA 12 are disposed on the temple 14, and the glasses frame 15 is internally provided with a light guide element (not shown) to enable the image projector 11 to project an image on the eyeglasses 13.

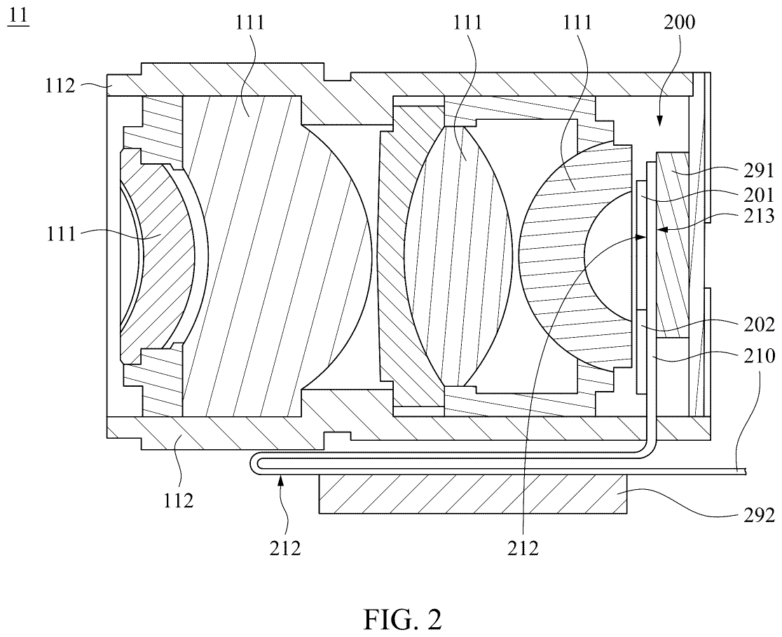

FIG. 2 is a cross-section schematic diagram of an image projector along the line 2-2 of FIG. 1. Referring to FIG. 1 and FIG. 2, the image projector 11 includes a display device 200, a lens-barrel 112 and a plurality of lenses 111, where these lenses and the display device 200 are disposed in the lens-barrel 112. At least two of these lenses 111 can be different from each other. For FIG. 2 as an example, the image projector 11 includes four lenses 111, in which the four lenses 111 have shapes in appearance which are different for each other.

The display device 200 includes a chipset 201, an electrical connection section 202, and a wiring substrate 210, where the chipset 201 and the electrical connection section 202 are all disposed on the wiring substrate 210. The wiring substrate 210 has an assembly surface 212, and the chipset 201 and the electrical connection section 202 are all disposed on the assembly surface 212. The electrical connection section 202 is electrically connected to the chipset 201 and the wiring substrate 210 so that the chipset 201 is electrically connected to the wiring substrate 210 via the electrical connection section 202. The wiring substrate 210 is electrically connected to the PCBA 12. In this way, the chipset 201 can be electrically connected to these electric components 122c, 122p, and 122s so that the electric signal can be delivery between the chipset 201 and the PCBA 12.

The wiring substrate 210 can be a flexible printed circuit board (FPCB), so that the wiring substrate 210 can be folded or bent, as shown in FIG. 2. In this embodiment, the wiring substrate 210 can utilize an anisotropic conductive film (ACF) to be electrically connected to the circuit board 121 of the PCBA 12, in which the circuit board 121 can be a general rigid printed circuit board. In addition, in other embodiment, the circuit board 121 and the wiring substrate 210 are integrated into a rigid-flexible circuit board.

The display device 200 also includes a first support element 291 and a second support element 292, in which the first support element 291 and the second support element 292 can both be metal plates and be all disposed on the wiring substrate 210. The first support element 291 and the second support element 292 are disposed on opposite surfaces of the wiring substrate 210 respectively. For example, in FIG. 2, the wiring substrate 210 also has a backside 213 opposite the assembly surface 212, where the first support element 291 is disposed on the backside 213, and the second support element 292 is disposed on the assembly surface 212. Furthermore, in the embodiment shown in FIG. 2, a part of the wiring substrate 210 can be sandwiched between the first support element 291 and the chipset 201.

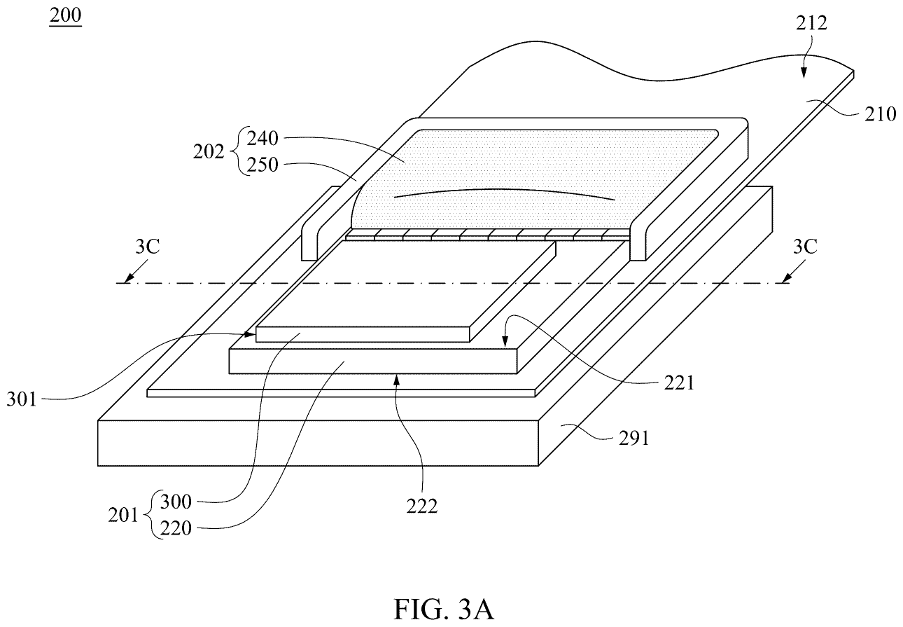

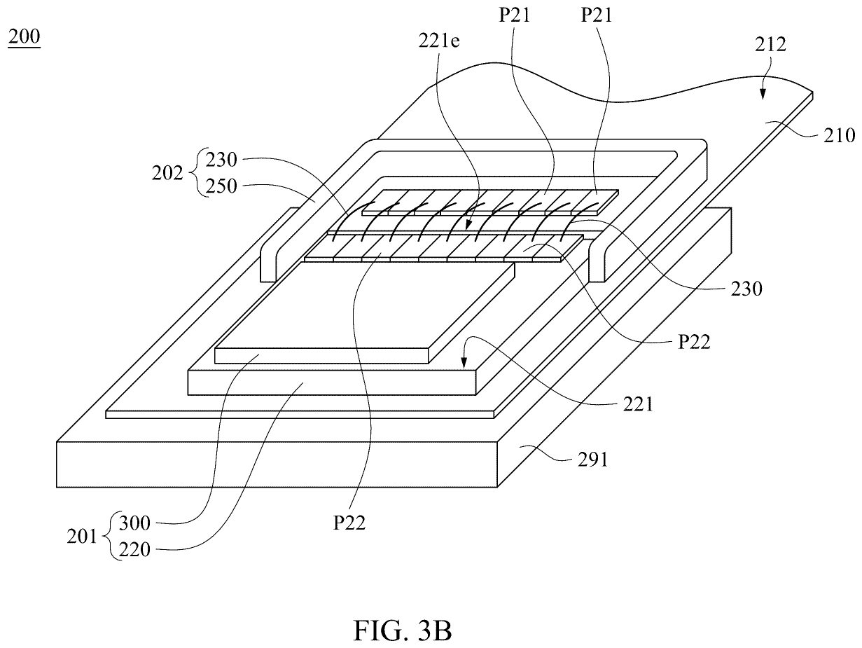

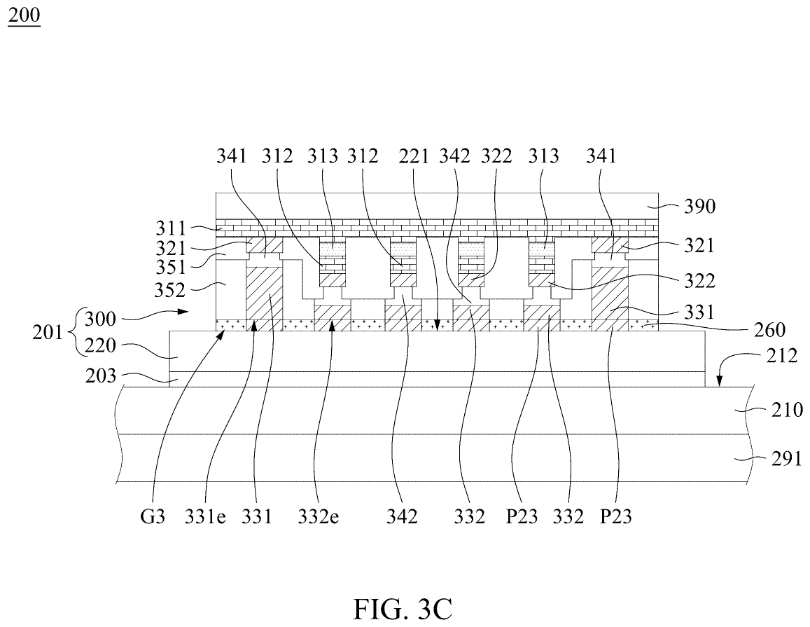

FIG. 3A is a three-dimensional schematic diagram of the display device of FIG. 2. Referring to FIG. 3A, the chipset 201 of the display device 200 includes a control chip 220 and a light emitting component 300, in which the light emitting component 300 is disposed on the control chip 220. The control chip 220 included in the display device 200 is disposed on the assembly surface 212 and has a first surface 221 and a second surface 222 opposite each other.

For example, in FIG. 3A, the first surface 221 and the second surface 222 can be the upper surface and lower surface of the control chip 220 respectively, where the second surface 222 is located between the assembly surface 212 and the first surface 221, and the light emitting component 300 is disposed on the first surface 221 of the control chip 220. Furthermore, as can be seen in FIG. 3A, the length and width of the control chip 220 is longer than the length and width of the light emitting component 300 such that the control chip 220 projects over each side 301 of the light emitting component 300.

The electrical connection section 202 of the display device 200 includes a protective plastic substance 240 and a fence 250. The protective plastic substance 240 and the fence 250 are both disposed on the assembly surface 212 of the wiring substrate 210, where the fence 250 surrounds the protective plastic substance 240. In this embodiment, both the protective plastic substance 240 and the fence 250 can be formed by curing a fluid adhesive, in which the abovementioned curing method can be heating. Both the protective plastic substance 240 and the fence 250 can include a resin material. For example, the structure material of the fence 250 can be silicone. Furthermore, the protective plastic substance 240 and the fence 250 can be formed without any mold, so that both the protective plastic substance 240 and the fence 250 have an irregularly distributed curved surface for the most part.

In this embodiment, both the color of the protective plastic substance 240 and the fence 250 can be different. For example, the color of the protective plastic substance 240 can be black, and the color of the fence 250 can be white. In addition to black and white, the colors of both the protective plastic substance 240 and the fence 250 can be other colors, such as yellow and green. Therefore, the colors of the protective plastic substance 240 and the fence 250 are not limited to black and white. Moreover, in other embodiment, the colors of the protective plastic substance 240 and the fence 250 can be the same as each other.

FIG. 3B is a three-dimensional schematic diagram of the display device in FIG. 3A after removing protective plastic substance. Referring to FIG. 3A and FIG. 3B, the wiring substrate 210 has a plurality of first pads P21 located on the assembly surface 212, and the control chip 220 includes a plurality of second pads P22 located on the first surface 221. The control chip 220 can be Complementary Metal-Oxide-Semiconductor Integrated Circuit (CMOS IC), in which these first pads P21 and these second pads P22 can be the pads of the Input/Output (I/O) of the wiring substrate 210 and the control chip 220, respectively.

Each of the second pads P22 is disposed between at least one of these first pads P21 and the light emitting component 300. For example, in FIG. 3B, the first surface 221 has an edge 221e, and these first pads P21 and these second pads P22 are adjacent to the edge 221e, and are all arranged along the edge 221e, where the edge 221e is disposed between the first pads P21 and the second pads P22. Moreover, in FIG. 3B, the shape of the edge 221e is substantially straight, in which these first pads P21 are lined up in a row along the edge 221e, and these second pads P22 are lined up in another row along the edge 221e.

The control chip 220 is electrically connected to the wiring substrate 210 utilizing wire bonding, and the electrical connection section 202 of the display device 200 also includes a plurality of bonding wires 230 for wire bonding. These bonding wires 230 are connected to these first pads P21 and these second pads P22 respectively so that the control chip 220 is electrically connected to the wiring substrate 210. In addition, since the first pads P21 and the second pads P22 can be the pads of the input/output (I/O) of both the wiring substrate 210 and the control chip 220 respectively, these bonding wires 230 is electrically connected to the pads of the input/output (I/O) of both the wiring substrate 210 and the control chip 220 enable the pads of the output/input of both the wiring substrate 210 and the control chip 220 to electrically conduct with each other.

Since the edge 221e is disposed between the first pads P21 and the second pads P22, these bonding wires 230 cross the edge 221e of the control chip 220, as shown in FIG. 3B. The protective plastic substance 240 encapsulates these bonding wires 230 to protect these bonding wires 230 from being struck and also to prevent at least two of the bonding wires 230 from touching each other, thereby preventing short circuits. In addition, the protective plastic substance 240 covers these first pads P21 so that the fence 250 surrounds not only the protective plastic substance 240, but also these first pads P21.

In the manufacturing process of the display device 200, the fence 250 is disposed on the assembly surface 212 of the wiring substrate 210 before the protective plastic substance 240 is disposed thereon. Thus, when the protective plastic substance 240 is disposed on the assembly surface 212, the fence 250 blocks the flow of the protective plastic substance 240 uncured so that the protective plastic substance 240 is confined to the area surrounded by the fence 250. In this way, the fence 250 can control the distribution area of the protective plastic substance 240 to prevent the overflow of the protective plastic substance 240, which in turn prevents the protective plastic substance 240 from covering components that are nor intended or suitable to be covered by the protective plastic substance 240.

Second, the fence 250 can limit the area over which the protective plastic substance 240 on the assembly surface 212 can be distributed, thereby controlling the amount of adhesive used to make the protective plastic substance 240. In this way, the fence 250 helps to prevent the waste of adhesive material for making the protective plastic substance 240, which reduces the cost of the adhesive material needed to make the protective plastic substance 240, which in turns helps to reduce the cost of the display device 200.

It is worth mentioning that since the colors of the protective plastic substance 240 and the fence 250 can be different from each other, for example, the black protective plastic substance 240 and the white fence 250, in the process of placing the protective plastic substance 240 on the assembly surface 212, it is easy for a worker or a machine to distinguish between the protective plastic substance 240 and the fence 250 by the color, so as to check whether the protective plastic substance 240 covers the top surface of the fence 250 and prevent the overflow of the protective plastic substance 240 from the outside of the fence 250.

FIG. 3C is a cross-section schematic diagram along the line 3C-3C of FIG. 3A. Referring to FIG. 3C, the chipset 201 is fixed on the wiring substrate 210. For example, the display device 200 also can include an adhesive layer 203. The adhesive layer 203 is disposed between the control chip 220 and the wiring substrate 210, and is connected to the control chip 220 and the wiring substrate 210, so that the chipset 201 can be bonded to the assembly surface 212 of the wiring substrate 210 via the adhesive layer 203. In addition, the adhesive layer 203 is an insulator, so the control chip 220 cannot be electrically connected to the wiring substrate 210 through the adhesive layer 203.

The light emitting component 300 is electrically connected to the control chip 220 so that the control chip 220 controls the light emitting component 300 to emit light. In particular, the control chip 220 further includes a plurality of third pads P23 located on the first surface 221, and the light emitting component 300 covers and is electrically connected to these third pads P23 to enable the light emitting component 300 to be electrically connected to the control chip 220 though the third pads P23.

In the embodiment shown in FIG. 3C, the light emitting component 300 can include a first doped semiconductor layer 311, a plurality of second doped semiconductor layers 312, and a plurality of quantum well layers 313. These quantum well layers 313 are disposed between the first doped semiconductor layer 311 and these second doped semiconductor layers 312, in which each of the quantum well layers 313 is sandwiched between the first doped semiconductor layer 311 and one of the second doped semiconductor layers 312.

The main of constituent materials of the first doped semiconductor layer 311 and the second doped semiconductor layers 312 can be gallium nitride (GaN). In this embodiment, the first doped semiconductor layer 311 can be an N-type gallium nitride layer, and the second doped semiconductor layers 312 can be a P-type gallium nitride layer. In opposite, in other embodiments, the first doped semiconductor layer 311 can be a P-type gallium nitride layer and the second doped semiconductor layers 312 can be an N-type gallium nitride layer. In addition, each of the quantum well layers 313 can be a multiple quantum well layer.

The light emitting component 300 can also include a plurality of first electrodes 321 and a plurality of second electrodes 322. These first electrodes 321 are electrically connected to the first doped semiconductor layer 311, and these second electrodes 322 are electrically connected to these second doped semiconductor layers 312 respectively. In addition, both the first electrodes 321 and the second electrodes 322 can be composed of the same material, and both can be multilayer films. For example, both the first electrodes 321 and the second electrodes 322 can be titanium/aluminum/titanium/gold multilayer films or chromium/platinum/gold multilayer films.

In this embodiment, since the first doped semiconductor layer 311 is an N-type gallium nitride layer and the second doped semiconductor layer 312 is a P-type gallium nitride layer, the first electrode 321 is a cathode and the second electrode 322 is an anode. However, in other embodiments, the first doped semiconductor layer 311 can be a P-type gallium nitride layer and the second doped semiconductor layer 312 can be an N-type gallium nitride layer, so that the first electrode 321 can be an anode and the second electrode 322 can be a cathode.

The light emitting component 300 can also include a plurality of first extension electrodes 331, a plurality of second extension electrodes 332, a plurality of first conductive portions 341 and a plurality of second conductive portions 342. These first conductor portions 341 is connected to these first electrodes 321 and these first extension electrodes 331 respectively, so that these first extension electrodes 331 are electrically connected to these first electrodes 321 respectively, where the first conductor portions 341 can be solder. These second conductor portions 342 are connected to these second electrodes 322 and these second extension electrodes 332 respectively, so that these second extension electrodes 332 are electrically connected to these second electrodes 322 respectively, where the second conductor portions 342 can also be solder.

It is noteworthy mentioning that, as can be seen from FIG. 3C, the lengths of the respective first extension electrodes 331 are significantly larger than the lengths of the respective second extension electrodes 332, so that end surfaces 331e of these first extension electrodes 331 can be substantially aligned with end surfaces 332e of these second extension electrodes 332. In other words, these end surfaces 331e and these end surfaces 332e can be co-planer so that these first extension electrodes 331 and these second extension electrodes 332 of the light emitting component 300 can be easily and securely connected to these third pads P23 respectively.

In this way, though the connection between the first extension electrodes 331 and the second extension electrodes 332 and the third pads P23, the light emitting component 300 can be electrically connected to the control chip 220 so that the control chip 220 can control the light emitting component 300 to emit light. In addition, the method of connecting both the first extension electrodes 331 and the second extension electrodes 332 to the third pads P23 can be eutectic bonding.

The light emitting component 300 can also include insulating layers 351, 352 and a light transmitting substrate 390. The light transmitting substrate 390 is disposed on the first doped semiconductor layer 311, and the insulating layers 351 and 352 are disposed on a lower surface of the first doped semiconductor layer 311, in which the first doped semiconductor layer 311 is disposed between the insulating layers 352 and the light transmitting substrate 390, and the insulating layers 351 and 352 are disposed between the first doped semiconductor layer 311 and the control chip 220. The light transmitting substrate 390 can be a glass plate or a sapphire substrate, and the constituent material of the insulating layers 351 and 352 can be an inorganic material, such as at least one of silicon oxide and silicon nitride. In addition, the insulating layers 351 and 352 can be formed by Chemical Vapor Deposition (CVD).

When the first extension electrodes 331 and the second extension electrodes 332 are electrified, e.g., the first extension electrodes 331 are electrified negatively and the second extension electrodes 332 are electrified positively, these quantum well layers 313 emit light, in which the aforesaid light penetrates through the light transmitting substrate 390 and exits from the light transmitting substrate 390. In the embodiment shown in FIG. 3C, the light emitting component 300 includes four quantum well layers 313, so that one of the light emitting component 300 has essentially four light emitting sources.

However, the light emitting component in other embodiments can include only one of the quantum well layers 313, and the light emitting component 300 in FIG. 3C can be replaced by at least two of the aforementioned light emitting components. Alternatively, the display device 200 can include a plurality of light emitting components 300. Thus, the number of the light emitting components 300 including in the display device 200 and the number of the quantum well layers 313 including in the light emitting components 300 are not limited by the schema (e.g., FIG. 3C), i.e., there is no limitation that the number of the light emitting components 300 including in the display device 200 is only one, and there is no limitation that the number of the quantum well layers 313 including in the light emitting components 300 is four.

The display device 200 can also include a colloid 260, in which the colloid 260 is disposed on the control chip 220 and surrounds these third pads P23. For example, in FIG. 3C, there is a gap G3 between the light emitting component 300 and the control chip 220, and the colloid 260 fills the gap G3. The color of the colloid 260 can be gray or black, in which the black color of the colloid 260 can help to improve the image contrast of the display device 200, and thus improve the picture quality of the display device 200.

The colloid 260 before curing can be a liquid, and the colloid 260 can be formed on the first surface 221 of the control chip 220 by injection. It should be noted that in this embodiment, the colloid 260 is filling the whole gap G3. However, in other embodiments, the colloid 260 can be formed only at the edges of the light emitting component 300 and retain all or a portion of the gap G3. Thus, the colloid 260 shown in FIG. 3C is for illustrative purposes only and is not a limitation of the present disclosure.

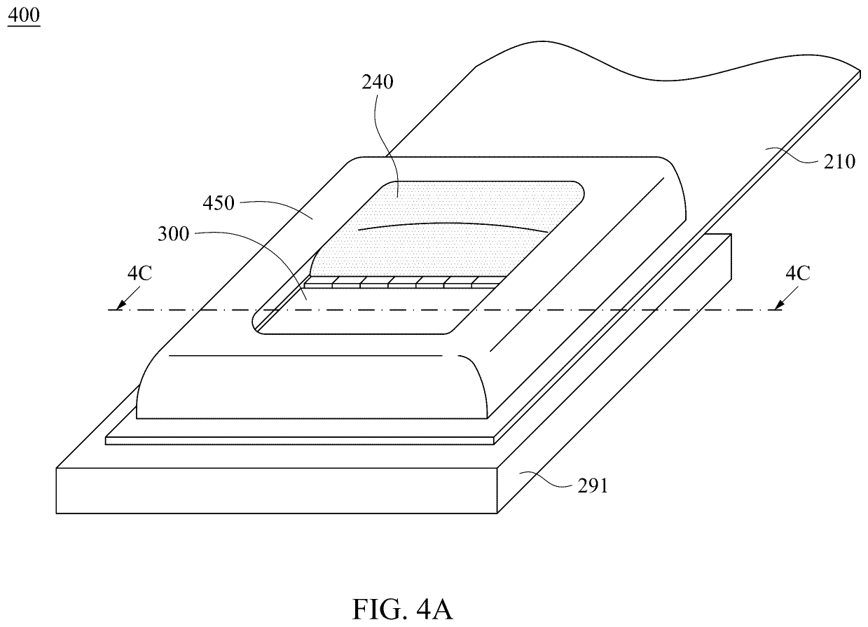

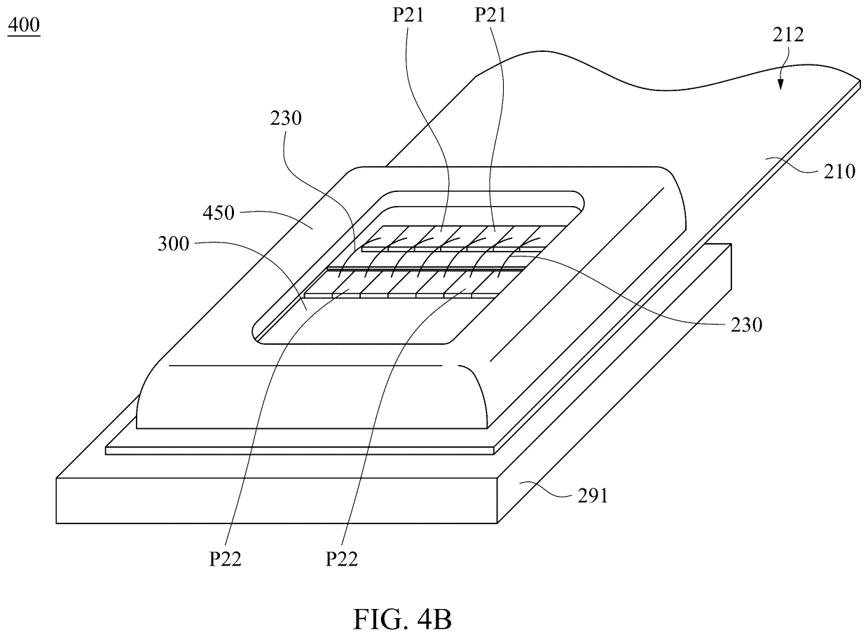

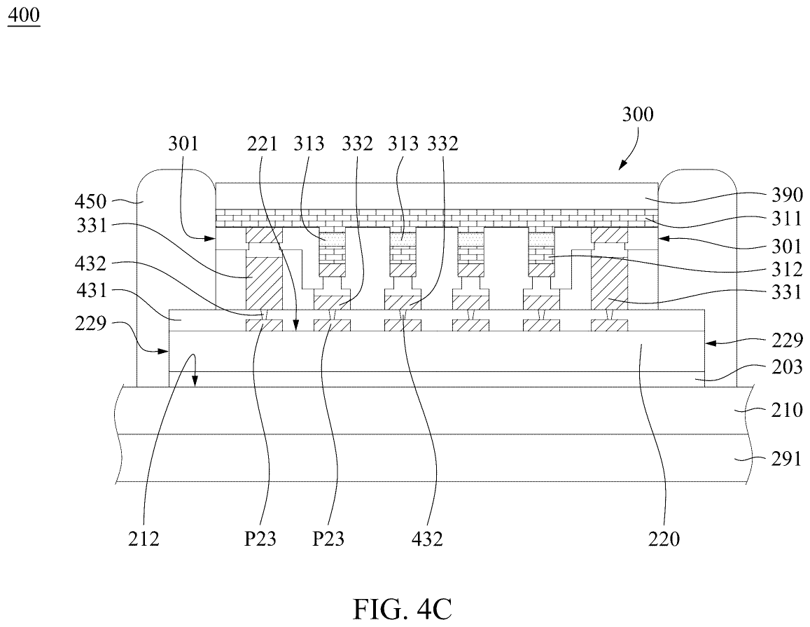

FIG. 4A is a three-dimensional schematic diagram of a display device of at another embodiment of the present disclosure, and FIG. 4B is a three-dimensional schematic diagram of the display device in FIG. 4A without the protective plastic substance. Please refer to FIG. 4A and FIG. 4B. A display device 400 is similar to the display device 200 aforementioned, in which the display devices 200 and 400 include the same or similar components, such as the wiring substrate 210, the first support element 291, the light emitting component 300, the bonding wires 230, and the protective plastic substance 240. The following describes the differences between the display devices 400 and 200, and the same features of the display devices 400 and 200 are not repeated.

The display device 400 includes a fence 450, in which the fence 450 and 250 can be constructed of the same material, i.e., the fence 450 can be constructed of a silicone resin. Unlike the display device 200 aforementioned, the fence 450 surrounds not only the protective plastic substance 240 and the first pads P21, but also the light emitting component 300 and the second pads P22, as shown in FIG. 4A and FIG. 4B.

FIG. 4C is a cross-section schematic diagram along the line 4C-4C of FIG. 4A. Referring to FIG. 4A and FIG. 4B, the fence 450 covers a plurality of sides 301 of the light emitting component 300. For example, the shape of the light emitting component 300 is a rectangular plate, so the light emitting component 300 has four sides 301, in which the fence 450 covers these sides 301. Moreover, in this embodiment, the display device 400 also includes the control chip 220, in which the control chip 220 can be adhered to the assembly surface 212 of the wiring substrate 210 via the adhesive layer 203. The fence 450 covers not only all sides 301 of the light emitting component 300, but also all sides 229 of the control chip 220, as shown in FIG. 4C.

It is worth mentioning that unlike the display device 200, the display device 400 includes an insulating layer 431 and a plurality of metallic pillars 432. Both the insulating layer 431 and these metallic pillars 432 can be disposed between the first surface 221 and the light emitting component 300, in which the insulating layer 431 covers these third pads P23, and these metallic pillars 432 are disposed on these third pads P23 respectively and are connected to these third pads P23 through the insulating layer 431. These metallic pillars 432 can be electrically connected to these first extension electrodes 331 and these second extension electrodes 332 respectively, so that the light emitting component 300 is electrically connected to the control chip 220 through these metallic pillars 432. Moreover, the metallic pillars 432 can be electrically connected to the first extension electrodes 331 and the second extension electrodes 332 by utilizing eutectic bonding.

The constituent material of the insulating layer 431 can be an inorganic material, such as silicon oxide or silicon nitride, and the constituent material of the metallic pillars 432 can be tungsten. The method of forming the insulating layer 431 with these metallic pillars 432 may include the following steps. First, the insulating layer 431 can be formed on the first surface 221 of the control chip 220 using chemical vapor deposition. At this time, the insulating layer 431 fully covers all of the third pads P23. Thereafter, the insulating layer 431 is patterned to form a plurality of holes in the insulating layer 431, where the method of patterning the insulating layer 431 can include photolithography and etching.

Thereafter, utilizing CVD or Physical Vapor Deposition (PVD) to deposit a metallic material on the insulating layer 431 and in these holes, such as tungsten. Afterward, a polishing process is performed to remove the metallic material located outside of these holes and retain the metallic material that fills these holes, thereby forming the metallic pillars 432, in which the polishing process can be Chemical-Mechanical Planarization (CMP).

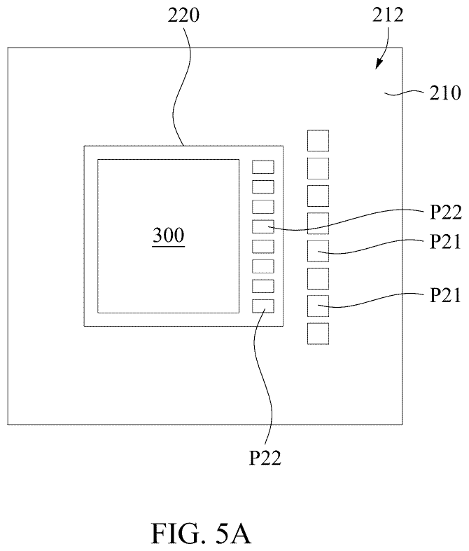

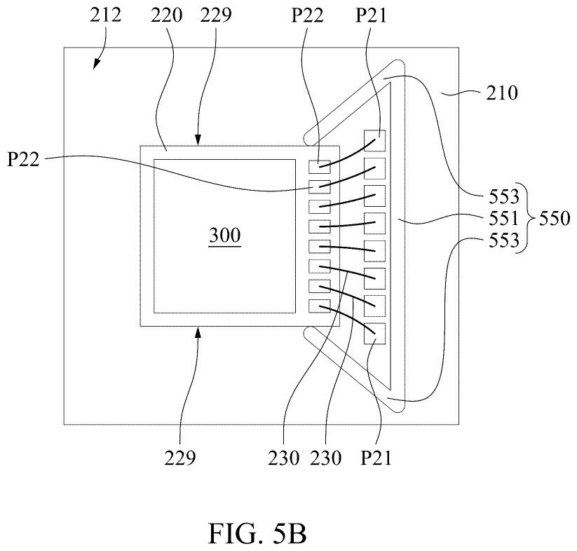

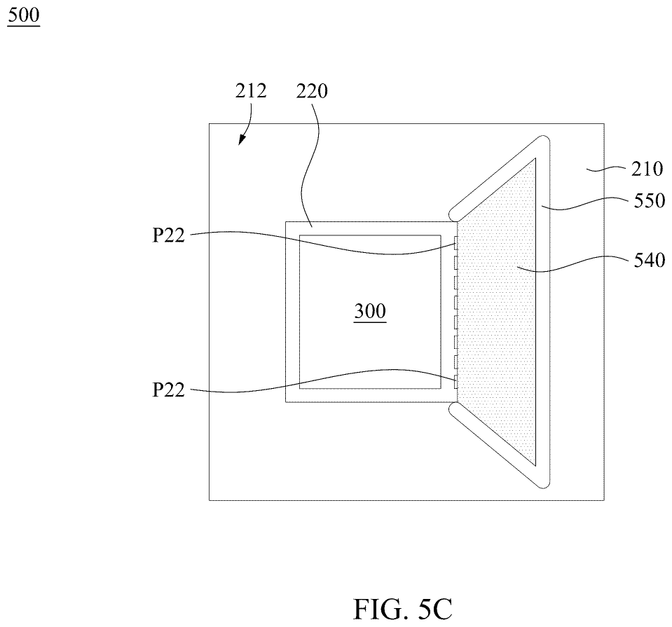

FIG. 5A to FIG. 5C are top view schematic diagrams of manufacturing a display device of at least one embodiment of the present disclosure, in which FIG. 5C discloses a display device 500 after manufacturing is completed. Referring first to FIG. 5C, the display device 500 is similar to the display devices 200 and 400 aforementioned, except that the display device 500 differs from the display devices 200 and 400 mainly in that the display device 500 includes a fence 550 that is different from the fence 250 and 450 aforementioned. Furthermore, the method of manufacturing the display device 500 disclosed in FIG. 5A to FIG. 5C is similar to the method of manufacturing the display devices 200 and 400. In other words, the display devices 200 and 400 can be manufactured substantially in the same method as disclosed in FIG. 5A to FIG. 5C.

The following describes first the method of manufacturing the display device 500. Referring to FIG. 5A, first, the at least one of the light emitting component 300 and the control chip 220 are disposed on the assembly surface 212 of the wiring substrate 210, in which the control chip 220 is electrically connected to the light emitting component 300, and the control chip 220 can be adhered to the assembly surface 212 via the adhesive layer 203 (shown in FIG. 3C and FIG. 4C). The adhesive layer 203 is insulator, so the control chip 220 and the light emitting component 300 are not electrically connected to the wiring substrate 210 at this time. Furthermore, since the number of the light emitting components 300 including in the display device 200 is not limited to only one, in other embodiments, a plurality of light emitting components 300 can be disposed on the first surface 221 of the same control chip 220.

Referring to FIG. 5B, thereafter, a plurality of bonding wires 230 and a fence 550 are provided on the assembly surface 212 of the wiring substrate 210, in which the order in which these bonding wires 230 and the fence 550 are provided is not limited. That is, these bonding wires 230 can be disposed of earlier or later than the fence 550. The material of construction of the fence 550 can be the same as the material of construction of the fence 250 and 450, such as silicone resin. Thus, the fence 250, 450, and 550 are only different in shape, but the methods of formation and the materials used to form them can be the same as each other.

In this embodiment, the fence 550 can include a first wall 551 and a pair of sidewalls 553, in which these sidewalls 553 are connected to the first wall 551 and the first wall 551 is disposed between these sidewalls 553. The first wall 551 is located on the assembly surface 212 and projects on opposite the two sides 229 of the control chip 220, and these first pads P21 and second pads P22 are located between the first wall 551 and the light emitting component 300. These sidewalls 553 are not parallel or perpendicular to each other. For example, the distance between these sidewalls 553 decreases gradually from the first wall 551 toward the control chip 220 so that the light emitting component 300 surrounds a trapezoidal area with the fence 550, as shown in FIG. 5B.

Referring to FIG. 5B and FIG. 50, after forming the fence 550, a protective plastic substance 540 is formed within the area surrounded by the fence 550 (e.g., the aforementioned trapezoidal area), where the protective plastic substance 540 covers these first pads P21 and these second pads P22 and covers these bonding wires 230 in order to protect these bonding wires 230 as well as to prevent short circuits. Thus, the display device 500 including the protective plastic substance 540 and the fence 550 is substantially complete. It is worth noting that the only difference between the protective plastic substances 540 and 240 is the shape. The protective plastic substances 540 and 240 are composed of the same materials, colors, and curing methods as each other, so we do not repeat the details.

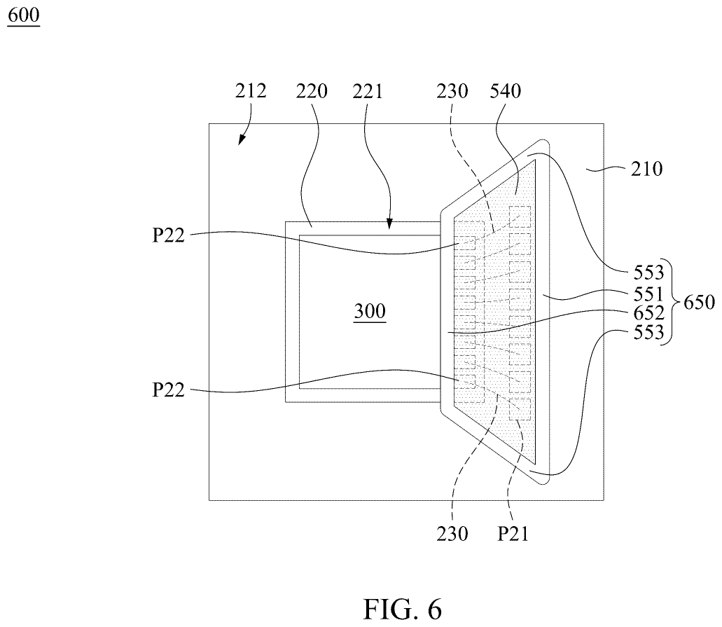

FIG. 6 is a top view schematic diagram of a display device of at least one embodiment of the present disclosure. Referring to FIG. 6, a display device 600 of the present embodiment is similar to the display device 500 of the previous embodiment, and both the display devices 500 and 600 have the same efficacy. The following is a main description of the features that differentiate the display devices 500 and 600, and the features that are common to both are not repeated.

A fence 650 including in the display device 600 is different from the fence 550 of the display device 500 aforementioned. In detail, the fence 650 shown in FIG. 6 includes a first wall 551 and a pair of sidewalls 553, in which these sidewalls 553 are connected to the first wall 551 and the first wall 551 is disposed between these sidewalls 553. However, unlike the fence 550, the fence 650 also includes a second wall 652 disposed on the assembly surface 212 and connected to these sidewalls 553.

The second wall 652 is disposed opposite the first wall 551 and is also disposed between the light emitting component 300 and these second pads P22, in which at least a portion of the second wall 652 can be disposed on the first surface 221, such as the whole of the second wall 652 shown in FIG. 6 can be disposed on the first surface 221. Thus, the protective plastic substance 540 is limited by the fence 650 to cover these first pads P21 and these second pads P22 of the wiring substrate 210.

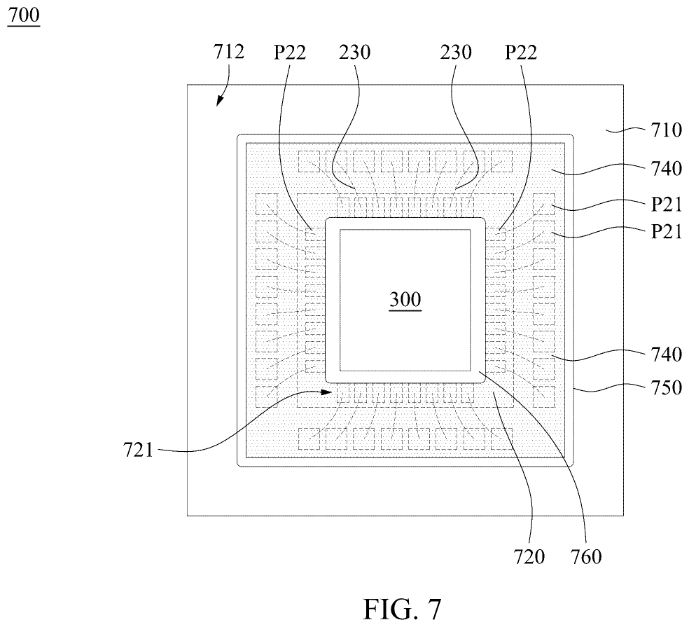

FIG. 7 is a top view schematic diagram of a display device of another embodiment of the present disclosure. Referring to FIG. 7, a display device 700 of the present embodiment includes a wiring substrate 710, a control chip 720, a light emitting component 300, a plurality of bonding wires 230, a protective plastic substance 740, and a fence 750. The wiring substrate 710 has an assembly surface 712 and a plurality of first pads P21 disposed on the assembly surface 712. The control chip 720 is disposed on the assembly surface 712 and includes a plurality of second pads P22.

Each of the second pads P22 is disposed between at least one of these first pads P21 and the light emitting component 300. In FIG. 7, for example, these second pads P22 surround the light emitting component 300, and these first pads P21 surround these second pads P22 with the light emitting component 300. In other words, these first pads P21 and these second pads P22 essentially surround the light emitting component 300 in a concentric ring arrangement, as shown in FIG. 7.

The display device 700 is similar to the display devices 200, 400, and 500 aforementioned. For example, the display device 700 has the same efficacy as the display devices 200, 400, and 500, and the display device 700 has a cross-sectional structure similar to that of the display device 200 or 400, as shown in FIG. 3C or FIG. 4C, in which the control chip 720 has a first surface 721 opposite each other and a second surface (not depicted), and the second surface is disposed between the assembly surface 712 and the first surface 721. In addition, these second pads P22 are located on the first surface 721.

The light emitting component 300 is disposed on the first surface 721 and is electrically connected to the control chip 720. These bonding wires 230 are connected to these first pads P21 and these second pads P22 respectively. The protective plastic substance 740 is disposed on the assembly surface 712 and the first surface 721 and covers these bonding wires 230 to protect these bonding wires 230 as well as to prevent short circuits. The protective plastic substance 740 covers these first pads P21 and these second pads P22, so that the protective plastic substance 740 surrounds the light emitting component 300. In addition, the construction materials, colors, and curing methods of the protective plastic substances 740 and 240 are the same as each other, so they are not repeated.

The fence 750 is disposed on the assembly surface 712 and surrounds these first pads P21, these second pads P22, the protective plastic substance 740, the light emitting component 300, and the control chip 720. Unlike the aforementioned embodiments, the display device 700 also includes a perimeter fence 760. The perimeter fence 760 is disposed on the first surface 721 of the control chip 720 and surrounds the light emitting component 300, in which the protective plastic substance 740 surrounds the perimeter fence 760 and the fence 750 surrounds the perimeter fence 760. Specifically, the fence 750 and the perimeter fence 760 will form a closed ring area on the assembly surface 712 and the first surface 721, and the protective plastic substance 740 will be confined to this ring area, as shown in FIG. 7, in order to prevent the overflow of the protective plastic substance 740.

In summary, with the above-disclosed fence, the protective plastic substance can be confined to the area surrounded by the fence, i.e., the fence can confine the protective plastic substance on the assembly surface to avoid the overflow of the protective plastic substance.

Although the present application has been disclosed in various embodiments as above, it is not intended to limit the present application and any person with common knowledge in the field of technology may make some changes and embellishments without departing from the spirit and scope of this application, and therefore the scope of protection of this application shall be subject to the scope of the patents applied for, as defined in the appended patent application.

What is claimed is:

1. A display device, comprising:
a wiring substrate, having an assembly surface and a plurality of first pads;
a control chip, disposed on the assembly surface and having a first surface and a second surface, the second surface located between the assembly surface and the first surface, wherein the control chip comprises a plurality of second pads disposed on the first surface;
a light emitting component, disposed on the first surface and electrically connected to the control chip, wherein each of the second pads are located between the light emitting component and at least one of the plurality of first pads;
a plurality of bonding wires, connected to the first pads and the second pads respectively;
a protective plastic substance, disposed on the assembly surface and encapsulating the bonding wires; and
a fence, disposed on the assembly surface and surrounding the first pads and the protective plastic substance.

2. The display device of claim 1, wherein the fence further surrounds the light emitting component and covers a plurality of sides of the light emitting component.

3. The display device of claim 1, wherein the first surface has an edge, and the second pads are adjacent to the edge and arranged along the edge, wherein the bonding wires cross the edge.

4. The display device of claim 3, wherein the first pads are arranged along the edge.

5. The display device of claim 1, further comprising:
a colloid, disposed on the control chip, wherein the control chip further comprises a plurality of third pads disposed on the first surface,
wherein the light emitting component covers and is electrically connected to the third pads and the colloid surrounds the third pads.

6. The display device of claim 5, wherein a gap exists between the light emitting component and the control chip, and the colloid fills the gap.

7. The display device of claim 5, wherein the control chip further comprises a plurality of the third pads disposed on the first surface, and the light emitting component covers and is electrically connected to the third pads, wherein the display device further comprises:
an insulating layer, covering the third pads; and
a plurality of metallic pillars, disposed on the third pads respectively, passing through the insulating layer, and connected to the third pads.

8. The display device of claim 1, wherein the fence comprise:
a first wall, disposed on the assembly surface, and projecting out two opposite sides of the control chip, wherein the first pads are disposed between the first wall and the control chip; and
a pair of sidewalls, connected to the first wall, wherein the first wall is disposed between the sidewalls, and a distance between the sidewalls decreases gradually from the first wall toward the control chip.

9. The display device of claim 8, wherein the fence further comprises:
a second wall, disposed on the assembly surface and on an opposite side of the first wall, and connected to the sidewalls, wherein the second wall is disposed between the light emitting component and the second pads.

10. The display device of claim 1, further comprising:
a perimeter fence, disposed on the first surface and surrounding the light emitting component, wherein the protective plastic substance surrounds the perimeter fence, and the fence surrounds the perimeter fence.

11. The display device of claim 1, wherein the light emitting component further comprising:
a first doped semiconductor layer;
a plurality of second doped semiconductor layers; and
a plurality of quantum well layers, disposed between the first doped semiconductor layer and the second doped semiconductor layers, wherein each of the plurality of quantum well layers is sandwiched between the first doped semiconductor layer and one of the second doped semiconductor layers.

12. The display device of claim 11, wherein the light emitting component further comprising:
a plurality of first electrodes, electrically connected to the first doped semiconductor layer; and
a plurality of second electrodes, electrically connected to the second doped semiconductor layers respectively.

13. The display device of claim 12, wherein the light emitting component further comprising:
a plurality of first extension electrodes;
a plurality of second extension electrodes;
a plurality of first conductive portions, connected to the first electrodes and the first extension electrodes respectively; and
a plurality of second conductive portions, connected to the second electrodes and the second extension electrodes respectively.

14. The display device of claim 11, wherein the light emitting component further comprising:
a light transmitting substrate, disposed on the first doped semiconductor layer.

15. A display device, comprising:
a wiring substrate, having an assembly surface and a plurality of first pads;
a control chip, disposed on the assembly surface and having a first surface and a second surface, the second surface located between the assembly surface and the first surface, wherein the control chip comprises a plurality of second pads disposed on the first surface;
a light emitting component, disposed on the first surface and electrically connected to the control chip, wherein each of the second pads are located between the light emitting component and at least one of the plurality of first pads;
a plurality of bonding wires, connected to the first pads and the second pads respectively;
a protective plastic substance, disposed on the assembly surface and encapsulating the bonding wires;
a fence, disposed on the assembly surface and surrounding the first pads and the protective plastic substance; and
a colloid, disposed on the control chip, wherein the control chip further comprises a plurality of third pads disposed on the first surface,
wherein the light emitting component covers and is electrically connected to the third pads and the colloid surrounds the third pads,
wherein a color of the colloid is gray or black.
